(19) United States
(12) Patent Application Publication
(10) Pub. No.: US 2026/0293187 A1
(43) Pub. Date: Sep. 24, 2026

(54) BACKSIDE CONTACT WITH BOTTOM INNER SPACER

(71) Applicant: INTERNATIONAL BUSINESS MACHINES CORPORATION, Armonk, NY (US)

(72) Inventors: Sarbajit Singh, Albany, NY (US); Ruilong Xie, Niskayuna, NY (US); Ravikumar Ramachandran, Pleasantville, NY (US); Mahender Kumar, Clifton Park, NY (US); Kisik Choi, Watervliet, NY (US); Nicolas Jean Loubet, GUILDERLAND, NY (US); Reinaldo Vega, Mahopac, NY (US); Xiaoming Yang, Clifton Park, NY (US)

(21) Appl. No.: 19/082,510

(22) Filed: Mar. 18, 2025

(51) Int. Cl. H10D 30/00; H10D 30/01; H10D 62/10; H10D 62/13; H10D 64/01; H10D 84/83

(52) U.S. Cl. CPC H10D 30/502; H10D 30/0191; H10D 62/121; H10D 62/151; H10D 64/015; H10D 64/021; H10D 84/832

(57) ABSTRACT

A nanosheet semiconductor structure including a backside contact structure beneath a first source drain region, and a bottom inner spacer directly beneath a second source drain region adjacent to the backside contact structure.

### BACKGROUND

The present invention generally relates to semiconductor structures, and more particularly to nanosheet transistor structures having a backside contact and bottom inner spacer.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet FET includes a plurality of stacked nanosheets extending between a pair of source drain epitaxial regions. The device may be a gate-all-around device or transistor in which the gate surrounds a portion of the nanosheet channel. A nanosheet device contains one or more layers of semiconductor channel material portions having a vertical thickness that is substantially less than its width.

### SUMMARY

According to an embodiment of the present invention, a semiconductor structure is provided. The semiconductor structure may include a backside contact structure beneath a first source drain region, and a bottom inner spacer directly beneath a second source drain region adjacent to the backside contact structure.

According to another embodiment of the present invention, a semiconductor structure is provided. The semiconductor structure may include a backside contact structure beneath a first source drain region, and a bottom inner spacer directly beneath a second source drain region adjacent to the backside contact structure, where the backside contact structure is taller than the bottom inner spacer.

According to another embodiment of the present invention, a semiconductor structure is provided. The semiconductor structure may include a backside contact structure beneath a first source drain region, and a bottom inner spacer directly beneath a second source drain region adjacent to the backside contact structure, wherein a height of the backside contact structure is substantially equal to a height of the bottom inner spacer.

### BRIEF DESCRIPTION OF THE DRAWINGS

The following detailed description, given by way of example and not intended to limit the invention solely thereto, will best be appreciated in conjunction with the accompanying drawings, in which:

FIG. 1, a top view of a generic structure is shown to provide spatial context to the different cross-sectional views and structural orientations of the semiconductor structures shown in the subsequent figures;

FIG. 2-15 are cross-sectional views of the semiconductor structure during intermediate step of a method of fabricating nanosheet transistor structures according to an exemplary embodiment;

FIG. 2-11 and 16-21 are cross-sectional views of the semiconductor structure during intermediate step of a method of fabricating nanosheet transistor structures according to another exemplary embodiment;

FIG. 2 is a cross-sectional view of the semiconductor structure during an intermediate step of a method of fabricating nanosheet transistor structures according to an exemplary embodiment;

FIG. 3 is a cross-sectional view of the semiconductor structure after patterning the nanosheet layers into nanosheet fins and forming sacrificial gates according to an exemplary embodiment;

FIG. 4 is a cross-sectional view of the semiconductor structure after forming sidewall spacers, removing portions of the nanosheet fins to create individual nanosheet stacks and source drain openings according to an exemplary embodiment;

FIG. 5 is a cross-sectional view of the semiconductor structure after forming a dielectric liner according to an exemplary embodiment;

FIG. 6 is a cross-sectional view of the semiconductor structure after removing portions of the dielectric liner to form opening spacers and removing portions of the substrate according to an exemplary embodiment;

FIG. 7 is a cross-sectional view of the semiconductor structure after removing the opening spacers according to an exemplary embodiment;

FIG. 8 is a cross-sectional view of the semiconductor structure after forming inner spacers and bottom inner spacers according to an exemplary embodiment;

FIG. 9 is a cross-sectional view of the semiconductor structure after forming source drain regions, a dielectric layer, gate structures, and gate caps according to an exemplary embodiment;

FIG. 10 is a cross-sectional view of the semiconductor structure after forming a middle-of-line, a back-end-of-line, a carrier wafer according to an exemplary embodiment;

FIG. 11 is a cross-sectional view of the semiconductor structure after flipping the assembly and recessing the substrate according to an exemplary embodiment;

FIG. 12 is a cross-sectional view of the semiconductor structure after forming a backside dielectric layer and backside contact trenches according to an exemplary embodiment;

FIG. 13 is a cross-sectional view of the semiconductor structure after removing some of the bottom inner spacers according to an exemplary embodiment;

FIG. 14 is a cross-sectional view of the semiconductor structure after removing portions of the top semiconductor layer from within the backside contact trenches according to an exemplary embodiment;

FIG. 15 is a cross-sectional view of the semiconductor structure after forming backside contact structures and backside wiring layers according to an exemplary embodiment;

FIG. 16 is a cross-sectional view of the semiconductor structure after recessing the top semiconductor layer according to an exemplary embodiment;

FIG. 17 is a cross-sectional view of the semiconductor structure after forming a backside dielectric layer according to an exemplary embodiment;

FIG. 18 is a cross-sectional view of the semiconductor structure after forming a backside mask and backside contact trenches according to an exemplary embodiment;

FIG. 19 is a cross-sectional view of the semiconductor structure after removing some of the bottom inner spacers according to an exemplary embodiment;

FIG. 20 is a cross-sectional view of the semiconductor structure after removing portions of the backside dielectric layer from within the backside contact trenches according to an exemplary embodiment;

FIG. 21 is a cross-sectional view of the semiconductor structure after removing portions of the top semiconductor layer from within the backside contact trenches according to an exemplary embodiment;

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Complementary field effect transistors, including gate-all-around transistor devices and nanosheet transistor devices, have known advantages over conventional transistor structures in terms of density, performance, power consumption, and integration. However, fabricating device contacts on a backside of the wafer presents unique challenges. More specifically, for example, conventional backside contact and placeholder fabrication techniques result in reduced backside contact size due to placeholder trimming during substrate removal. Additionally, silicon germanium placeholder techniques become more challenging as dimensions scale.

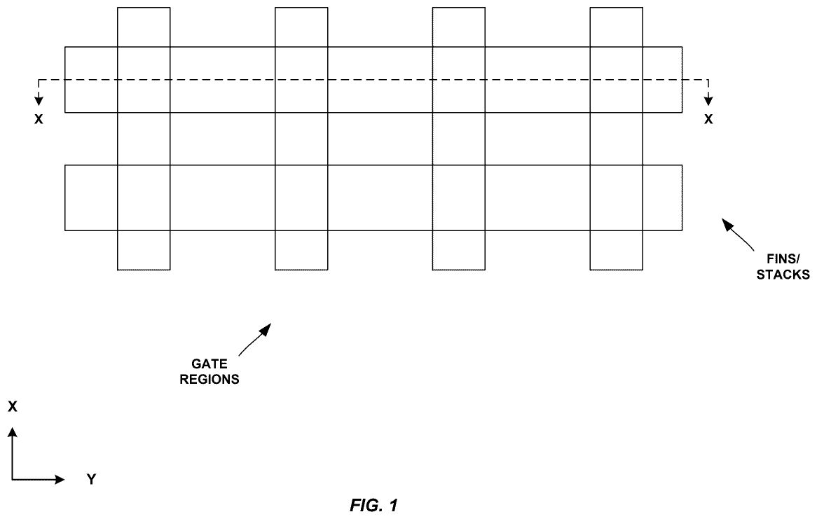

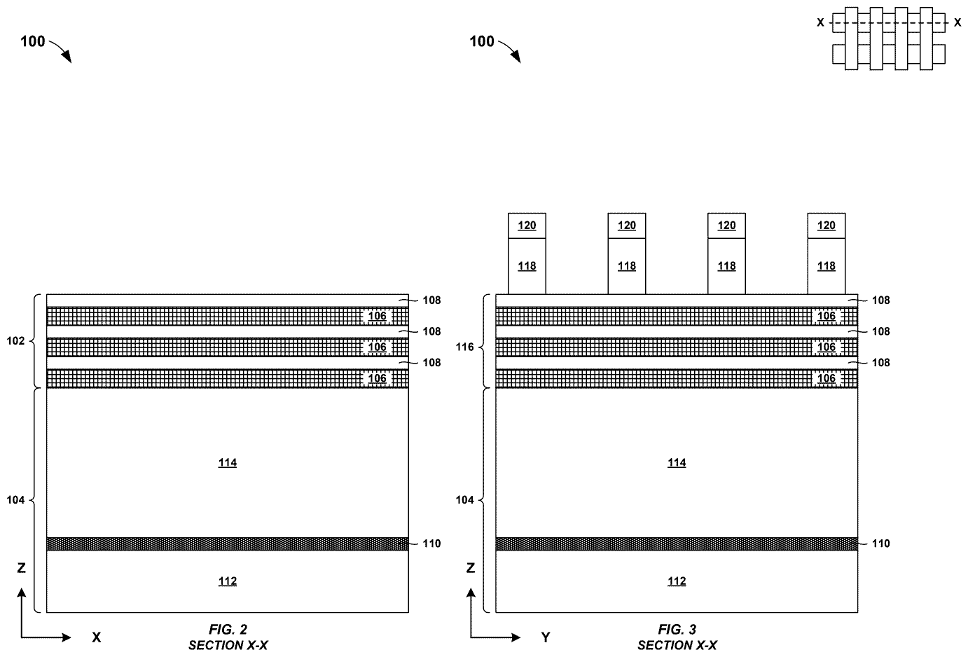

The present invention generally relates to semiconductor structures, and more particularly to nanosheet transistor structures having a backside contact and bottom inner spacer. More specifically, the nanosheet transistor structures and associated method disclosed herein enable a novel solution for providing nanosheet transistor structures having a backside contact and a bottom inner spacer. The bottom inner spacer is arranged directly below source drain regions and facilitate formation of the backside contact. Exemplary embodiments of nanosheet transistor structures having a backside contact and a bottom inner spacer are described in detail below by referring to the accompanying drawings in FIGS. 1 to 21. Specifically, FIG. 1 illustrates a top view of a generic structure to provide spatial context; FIG. 2-15 illustrate an embodiment; and FIG. 2-11 and 16-21 illustrate a different embodiment, with FIG. 2-11 being common to both embodiments. Those skilled in the art will readily appreciate that the detailed description given herein with respect to these figures is for explanatory purposes as the invention extends beyond these limited embodiments.

Referring now to FIG. 1, a top view of a generic structure is shown to provide spatial context to the different cross-sectional views and structural orientations of the semiconductor structures shown in the figures and described below. Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

The generic structure illustrated in FIG. 1 shows multiple fins/stacks and multiple gate regions situated perpendicular to one another. FIG. 2-21 represent cross section views oriented as indicated in FIG. 1

Referring now to FIG. 2, a structure 100 is shown during an intermediate step of a method of fabricating a nanosheet transistor structure according to an embodiment of the invention. FIG. 2 depicts a cross-sectional view taken along line X-X.

The structure 100 illustrated in FIG. 2 includes nanosheet layers 102 formed on a substrate 104. For purposes of orientation, the substrate 104 is herein referred to as being on a “backside” of the structure 100 and the nanosheet layers 102 are herein referred to as being on a “frontside” of the structure 100. Further, certain features may be described herein as having a relative position with respect to the frontside or backside of the structure 100.

The nanosheet layers 102 include an alternating series of silicon germanium (SiGe) sacrificial nanosheets 106 (hereinafter “sacrificial nanosheets 106”), silicon (Si) channel nanosheets 108 (hereinafter “channel nanosheets 108”), as illustrated. Specifically, for example, the nanosheet layers 102 include the channel nanosheets 108 separated from one another by the sacrificial nanosheets 106.

According to embodiments of the present invention, the nanosheet layers 102 include and three of the sacrificial nanosheets 106 and three of the channel nanosheets 108. Although only a discrete number of individual layers are shown, the nanosheet layers 102 may include any number of individual layers in any number of combinations. For example, according to an embodiment, the nanosheet layers 102 include less than three of the sacrificial nanosheets 106 and more than three of the channel nanosheets 108.

In one or more embodiments, the nanosheet layers 102 are formed by epitaxially growing one layer and then the next until a desired number and a desired thickness of each layer is achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) can be undoped or can be doped during deposition (in-situ doped) by adding dopants, n-type dopants (e.g., phosphorus or arsenic) or p-type dopants (e.g., boron or gallium), depending on the type of transistor. For example, the channel nanosheets 108 of the nanosheet layers 102 may be doped, undoped or some combination thereof.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments, epitaxial growth and/or deposition processes are selective to forming on semiconductor surfaces, and generally do not deposit material on exposed surfaces, such as silicon dioxide or silicon nitride surfaces.

In some embodiments, the gas source for the deposition of epitaxial semiconductor material includes a silicon containing gas source, a germanium containing gas source, or a combination thereof. For example, an epitaxial silicon layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

The substrate 104 may be a layered semiconductor such as a silicon-on-insulator or SiGe-on-insulator, where an etch stop layer 110 separates a base substrate 112 from a top semiconductor layer 114. Unlike conventional layered semiconductor substrates, the etch stop layer 110 of the substrate 104 may include any material which affects the desired etch selectivity during subsequent processing. For example, the etch stop layer 110 may be a conventional buried oxide layer, or it may be a silicon germanium layer with a specific germanium concentration. In practice, the etch stop layer 110 will function as an etch stop layer and can be composed of any material which supports that function. For example, according to an embodiment, the etch stop layer 110 is made from silicon germanium having a different germanium concentration than other layers in the structure 100.

In the present embodiment, both the base substrate 112 and the top semiconductor layer 114 may be any bulk substrate made from any of several known semiconductor materials such as, for example, silicon, germanium, silicon-germanium alloy, and compound (e.g. III-V and II-VI) semiconductor materials. For example, both the base substrate 112 and the top semiconductor layer 114 may be made from silicon. Additionally, at least both the etch stop layer 110 and the base substrate 112 are sacrificial and will not remain in the final structure.

Referring now to FIG. 3, the structure 100 is shown after patterning the nanosheet layers 102 into nanosheet fins 116 and forming sacrificial gates 118 according to an embodiment of the invention. FIG. 3 depicts a cross-sectional view taken along line X-X.

First, known processing techniques have been applied to pattern the nanosheet layers 102 to form the nanosheet fins 116, as shown. For example, the known processing techniques can include the formation of hard masks (not shown) over the topmost layer of the nanosheet layers 102. The hard masks can be formed by first depositing the hard mask material (for example silicon nitride) onto the topmost layer of the nanosheet layers 102 using, for example, chemical vapor deposition (CVD), plasma enhanced CVD (PECVD) or any suitable technique for dielectric deposition that does not induce a physical or chemical change to the topmost layer of the nanosheet layers 102. According to an exemplary embodiment, the hard mask material is deposited onto the topmost layer of the nanosheet layers 102 and then patterned into a plurality of the individual hard masks. Patterning the hard mask is commensurate with a desired footprint and location of the nanosheet fins 116 shown in the figures, and which will subsequently be used to form the channel regions of semiconductor devices disclosed herein. According to an exemplary embodiment, RIE is used to transfer the hard mask pattern into the nanosheet layers 102, and into the substrate 104. The remaining portions of the nanosheet layers 102 are hereafter referred to as the nanosheet fins 116.

Next, shallow trench isolation regions (hereinafter “STI regions”) are formed according to known techniques. The STI regions are formed at the bottom of trenches in the substrate 104 formed during patterning of the nanosheet layers 102 into the nanosheet fins 116, as illustrated. Specifically, a dielectric material is deposited at the bottom of trenches in the substrate 104 to isolate adjacent devices from one another according to known techniques. The STI regions may be formed from any appropriate dielectric material including, for example, silicon oxide (SiOₓ) or silicon nitride (SiₓN_{y}).

Next, a sacrificial gate dielectric is deposited directly on exposed surfaces of the structure 100 according to known techniques. Specifically, for example, a relatively thin layer of silicon oxide (SiO2) is first conformally deposited over and around the nanosheet fins 116.

As used herein, “conformal” it is meant that a material layer has a continuous thickness, or substantially continuous thickness. For example, a continuous thickness generally means a first thickness as measured from a bottom surface to a topmost surface that is the same as a second thickness as measured from an inner sidewall surface to an outer sidewall surface.

Next, a sacrificial gate material is blanket deposited over and around the nanosheet fins 116 according to known techniques. Specifically, for example, a relatively thick layer of amorphous silicon is blanket deposited directly on the sacrificial gate dielectric. In this manner, both the sacrificial gate dielectric and the sacrificial gate material completely cover the nanosheet fins 116.

Next, individual gate hard masks 120 are formed over the structure 100. The individual gate hard masks 120 define gate regions of individual devices. According to an exemplary embodiment, a mask material is deposited onto the sacrificial gate material and then patterned into the individual gate hard masks 120. Next, the pattern created by the individual gate hard masks 120 is transferred into the sacrificial gate dielectric and the sacrificial gate material. Specifically, portions of sacrificial gate dielectric and the sacrificial gate material are anisotropically etched or removed selective to the individual gate hard masks 120 to form the sacrificial gates 118, as illustrated. According to an embodiment, a silicon RIE process is used to selectively remove the portions of the sacrificial gate dielectric and the sacrificial gate material.

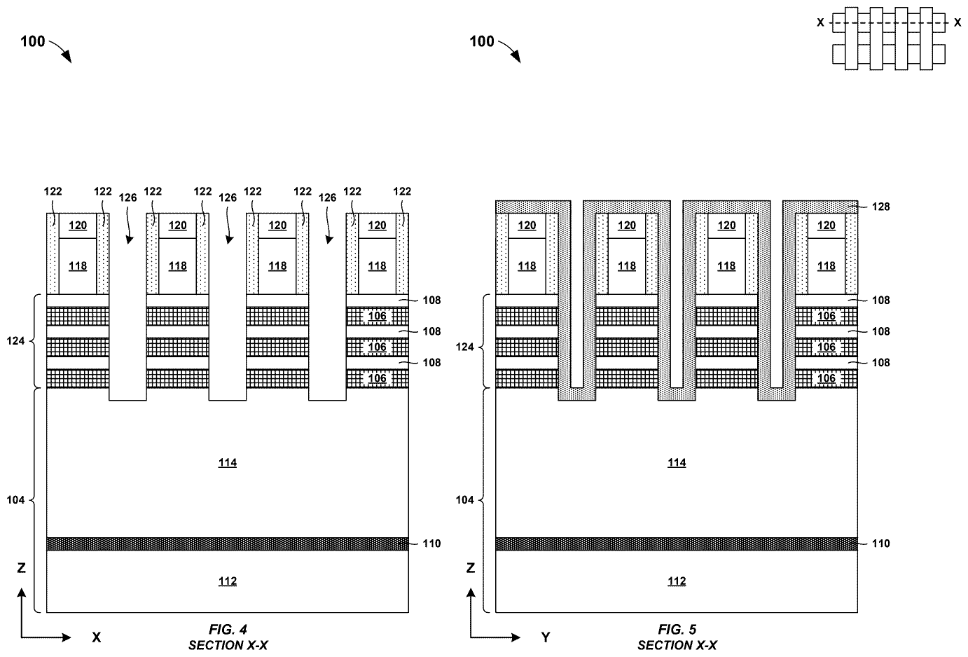

Referring now to FIG. 4, the structure 100 is shown after forming sidewall spacers 122, removing portions of the nanosheet fins 116 to create individual nanosheet stacks 124 and source drain openings 126 according to an embodiment of the invention. FIG. 4 depicts a cross-sectional view taken along line X-X.

The sidewall spacers 122 are formed by first depositing a conformal layer of dielectric material on top of the structure 100 according to known techniques. Specifically, the layer of dielectric material may be deposited directly on sidewalls of the sacrificial gates 118, sidewalls of the individual gate hard masks 120, and surfaces of the nanosheet fins 116 exposed between the sacrificial gates 118. In an embodiment, the layer of dielectric material can include, for example, SiN, SiBCN, SiOCN, SiC, SiOC, or any other combination of low-k materials. The term “low-k” as used throughout the present application denotes a dielectric material that has a dielectric constant of less than 4.0.

It may be preferable, in some cases, to fabricate the sidewall spacers 122 from a material having a substantially different etch rate than that of the surrounding materials to effect good etch selectivity during subsequent fabrication. In an embodiment, the layer of dielectric material may preferably include an oxide, for example, silicon oxide. The layer of dielectric material can be deposited with a conformal deposition technique, using any known atomic layer deposition technique, molecular layer deposition techniques, or other known conformal deposition techniques. In an embodiment, the layer of dielectric material can have a substantially conformal and uniform thickness ranging from about 5 nm to about 20 nm, and ranges there between.

Next, a directional anisotropic etching technique may be used to remove portions of the layer of dielectric material from horizontal surfaces of the structure 100, while leaving it on the sidewalls of the sacrificial gates 118 and on the sidewalls of the individual gate hard masks 120, as illustrated. For example, a reactive-ion-etching technique may be used to remove portions of the layer of dielectric material from directly above the nanosheet fins 116 and from top surfaces of the individual gate hard masks 120. The portions of the layer of dielectric material remaining along opposite sidewalls of the sacrificial gates 118 and the individual gate hard masks 120, form the sidewall spacers 122. Furthermore, the individual gate hard masks 120 and the sidewall spacers 122 should each include materials that would allow the individual gate hard masks 120 to be subsequently removed selective to the sidewall spacers 122. Here, it should also be noted that the sidewall spacers 122 depicted in the figures are for illustration purposes and generally can have a slightly different shape from those shown. For example, the sidewall spacers 122 can have rounded corners which may naturally form during the directional etching process as is known in the art.

The sidewall spacers 122 may have a lateral width substantially equal to the conformal thickness of the layer of dielectric material above. In an embodiment, the lateral width of the sidewall spacers 122 may preferably be sublithographic, or smaller than a lithographic minimum dimension. The term “sublithographic” may refer to a dimension or size less than current dimensions achievable by photolithographic processes, and the term “lithographic” or “lithographic minimum dimension” may refer to a dimension or size equal to or greater than current dimensions achievable by photolithographic processes. The sublithographic and lithographic dimensions may be determined by a person of ordinary skill in the art at the time the application is filed. While a “lithographic minimum dimension” and a “sublithographic dimension” are defined only in relation to a lithography tool and normally change from generation to generation of semiconductor technology, it is understood that the lithographic minimum dimension and the sublithographic dimension are to be defined in relation to the best performance of lithography tools available at the time of semiconductor manufacturing. As of 2015, the lithographic minimum dimension is about 20 nm and is expected to shrink in the future. In an embodiment, for example, the sidewall spacers 122 may have a lateral width ranging from about 5 nm to about 15 nm, and ranges there between. It is possible to adjust spacer width based on etch bias or loss of material during process to meet final technology target dimension. The sidewall spacers 122 help define active regions which may subsequently be transferred into underlying layers.

Next, the individual nanosheet stacks 124 and the source drain openings 126 are formed by removing portions of the nanosheet fins 116 according to known techniques. Specifically, the pattern created by the individual gate hard masks 120 and the sidewall spacers 122 is transferred into the nanosheet fins 116. In doing so, portions of the sacrificial nanosheets 106, the channel nanosheets 108, and the substrate 104 are removed, as illustrated.

In an embodiment, portions of the nanosheet fins 116 are removed using an anisotropic etch such as, for example, reactive ion etching. Doing so may require a series of multiple etching steps using different etch chemistries as is well known in the art. Etching is designed to define source drain regions and expose ends of individual nanosheet layers. In all cases, etching continues until at least the topmost surface of the substrate 104 is exposed. In some embodiments, as illustrated, etching continues until the source drain openings 126 extend into the top semiconductor layer 114.

Referring now to FIG. 5, the structure 100 is shown after forming a dielectric liner 128 according to an embodiment of the invention. FIG. 5 depicts a cross-sectional view taken along line X-X.

The dielectric liner 128 is formed across the frontside of the structure 100 according to known techniques. Specifically, a liner material is conformally deposited across exposed surfaces on the frontside of the structure 100 including within the source drain openings 126, as illustrated. In some embodiments, for example, the dielectric liner 128 may be composed of other low-k materials, such as, for example, SiN, SiBCN, SiOCN, SiOC, or other combinations thereof. In all cases, the dielectric liner 128 is preferably made from a material which may be removed selective to surrounding elements, such as, for example, the sacrificial nanosheets 106, the channel nanosheets 108, and the top semiconductor layer 114.

According to the disclose embodiments, the dielectric liner 128 shall be formed of a sufficient thickness to effectively reduce the critical dimension, for example width or diameter, of the source drain openings 126. According to an embodiment, the dielectric liner 128 has a conformal thickness of at least 2 nm to ensure a continuous film. Additionally, thickness of the dielectric liner 128 should be limited to prevent unwanted pinching-off or closing entirely of the source drain openings 126.

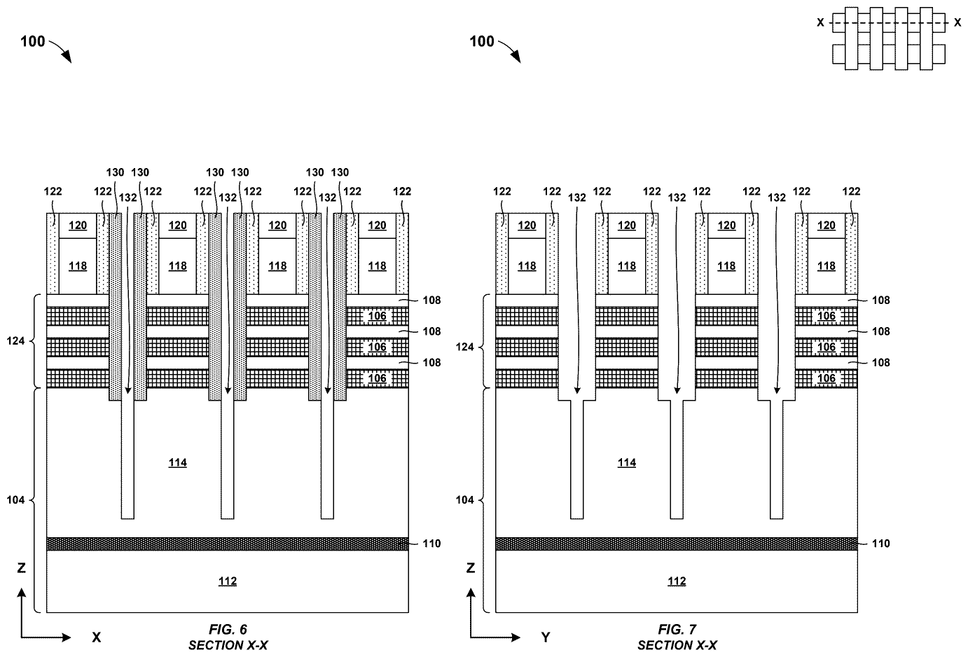

Referring now to FIG. 6, the structure 100 is shown after removing portions of the dielectric liner 128 to form opening spacers 130 and removing portions of the substrate 104 according to an embodiment of the invention. FIG. 6 depicts a cross-sectional view taken along line X-X.

First, portions of the dielectric liner 128 are removed according to known techniques. Specifically, portions of the dielectric liner 128 are substantially removed from horizontal surfaces to form the opening spacers 130. In doing so, portions of the of the dielectric liner 128, now the opening spacers 130, remain on sidewalls of the source drain openings 126, as illustrated. Known directional etching techniques, for example reactive ion etching, may be used to remove remaining portions of the dielectric liner 128 from horizontal surfaces. Doing so will remove portions of the dielectric liner material from tops of the structure 100 and bottoms of the source drain openings 126, as illustrated.

According to the disclosed embodiments, the opening spacers 130 remain along sidewall portions of the source drain openings 126, as illustrated. Said differently, portions of the dielectric liner 128 shall only be removed from substantially horizontal surfaces, as illustrated. According to an embodiment, the opening spacers 130 substantially cover and protect surfaces of the individual nanosheet stacks 124 within the source drain openings 126.

Next, portions of the substrate 104 are removed to form trenches 132 according to known techniques. Specifically, exposed portions of the top semiconductor layer 114 are removed using known etching techniques, as illustrated. In an embodiment, the portions of the substrate 104 are removed using an anisotropic etch such as, for example, reactive ion etching. In some embodiments, etching stops before exposing the etch stop layer 110 (as illustrated), while in other embodiments etching continues until the etch stop layer 110 is reached or exposed.

Referring now to FIG. 7, the structure 100 is shown after removing the opening spacers 130 according to an embodiment of the invention. FIG. 7 depicts a cross-sectional view taken along line X-X.

The opening spacers 130 are removed according to known techniques. Specifically, the opening spacers 130 are removed using known etching techniques suitable to remove silicon-based materials selective to the surrounding elements, for example the top semiconductor layer 114, the individual nanosheet stacks 124, the sidewall spacers 122, the individual gate hard masks 120. In an embodiment, the opening spacers 130 are removed using isotropic etching techniques. For example, if the opening spacers 130 are made from titanium or titanium oxide then a SCI wet clean may be used. After removing the opening spacers 130, sidewalls of the individual nanosheet stacks 124 become exposed, as best illustrated in FIG. 7.

For context, the opening spacers 130 are provided as a mask to enable forming of the trenches 132 in the top semiconductor layer 114. As such, the thickness of the dielectric liner 128, and similarly the opening spacers 130, is directly proportional to a width or diameter of each of the trenches 132. For example, reducing the thickness of the opening spacers 130 will effectively increase the width of each of the trenches 132.

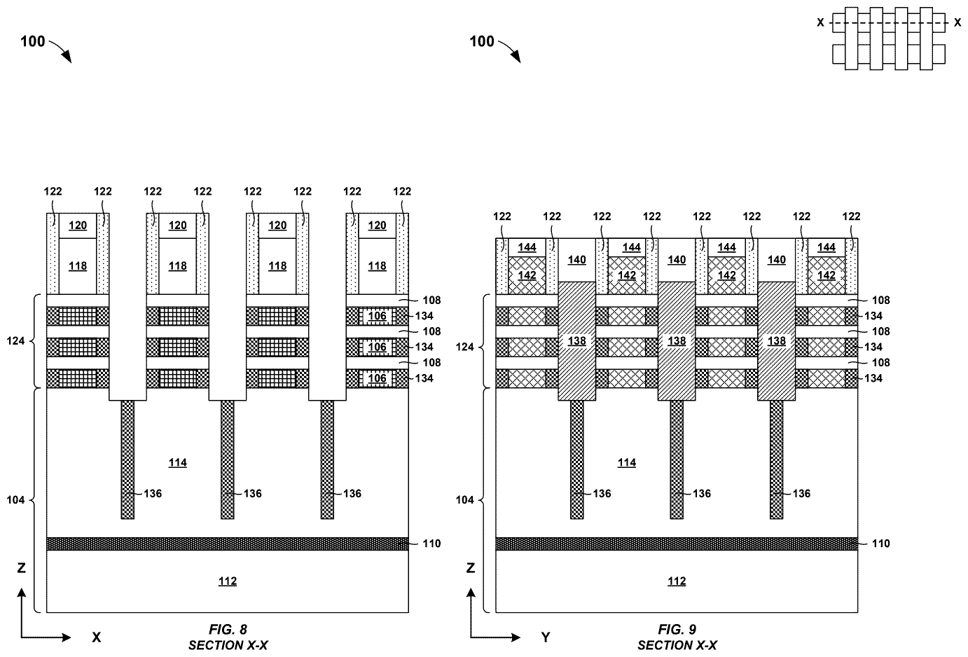

Referring now to FIG. 8, the structure 100 is shown after forming inner spacers 134 and bottom inner spacers 136 according to an embodiment of the invention. FIG. 8 depicts a cross-sectional view taken along line X-X.

First, the sacrificial nanosheets 106 are laterally recessed to make room for the inner spacers 134. In one or more embodiments, the sacrificial nanosheets 106 are laterally recessed using a hydrogen chloride (HCl) gas isotropic etch process, which etches silicon germanium without attacking silicon. In other embodiments, the sacrificial nanosheets 106 are laterally recessed using a ClF3 etch process. Cavities (not shown) are formed by spaces that were occupied by the removed portions of the sacrificial nanosheets 106.

Next, the inner spacers 134 and the bottom inner spacers 136 are formed by first conformally depositing a conformal spacer material over the structure 100 to fill the cavities created by laterally recessing the sacrificial nanosheets 106 and fill the trenches 132. The conformal spacer material is then isotropically etched to remove all portions except those portions remaining in the cavities and portions remaining in the trenches 132. The portions remaining in the cavities form the inner spacers 134 and the portions remaining in the trenches 132 form the bottom inner spacers 136.

In one or more embodiments, both the inner spacers 134 and the bottom inner spacers 136 are made from a nitride containing material, for example silicon nitride (SiN). Alternatively, the inner spacers 134 and the bottom inner spacers 136 are made from any material which offers selectivity for subsequent device fabrication operations. Selectivity, as used in the present description, refers to the tendency of a process operation to impact a particular material. One example of low selectivity is a relatively slow etch rate. One example of a higher or greater selectivity is a relatively faster etch rate. For the described embodiments, a material for the inner spacers 134 and the bottom inner spacers 136 can be selected, in part, based on a selectivity of subsequent device fabrication operations for the selected material being below a predetermined threshold.

Referring now to FIG. 9, the structure 100 is shown after forming source drain regions 138, a dielectric layer 140, gate structures 142, and gate caps 144 according to an embodiment of the invention. FIG. 9 depicts a cross-sectional view taken along line X-X.

First, the source drain regions 138 are formed using an epitaxial layer growth process on the exposed ends of the channel nanosheets 108 according to known techniques. Typically, in-situ doping is used to dope the source drain regions 138, thereby creating the necessary junctions of the semiconductor device. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a P-type piece of silicon, rich in holes, and an N-type piece of silicon, rich in electrons. N-type and P-type devices are formed by using different types of dopants to select regions of the device to form the necessary junction(s). For example, N-type devices can be formed by doping with arsenic (As) or phosphorous (P), and p-type devices can be formed by doping with implanting boron (B).

According to embodiments of the present invention, at least some of the source drain regions 138 are of a first-type, for example, P-type, and at least some of the source drain regions 138 are of a second-type, for example, N-type. Additionally, the source drain regions 138 are formed directly on top of the bottom inner spacers 136.

Next, the dielectric layer 140 is blanket deposited an interlayer dielectric material over the structure 100 according to known techniques. Specifically, the dielectric layer 140 is formed on the source drain regions 138, and substantially fills the remaining space between the sidewall spacers 122.

The dielectric layer 140 can be composed of silicon dioxide, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. In another embodiment, a self-planarizing material such as a spin-on glass (SOG) or a spin-on low-k dielectric material such as SiLK™ can be used as the dielectric layer 140. Using a self-planarizing dielectric material as the dielectric layer 140 can avoid the need to perform a subsequent planarizing step.

After the dielectric layer 140 is formed, the structure 100 is polished according to known techniques, such as, for example, chemical mechanical polishing techniques. Specifically, the dielectric layer 140, the sidewall spacers 122, and the individual gate hard masks 120 are polished until the individual gate hard masks 120 are removed and topmost surfaces of the sacrificial gates 118 are exposed.

Next, the sacrificial gates 118 are selectively removed according to known techniques. Specifically, the sacrificial gates 118 are etched and removed selective to the sidewall spacers 122 and the individual nanosheet stacks 124 according to known techniques.

Next, the sacrificial nanosheets 106 are etched and removed selective to the channel nanosheets 108, the inner spacers 134, and the top semiconductor layer 114 according to known techniques. Doing so is made possible, in part, by the different concentrations of germanium. In this case, the layers with germanium are removed selective to layers without germanium.

Next, the gate structures 142, including a gate dielectric and a work function metal, are formed according to known techniques. First, the gate dielectric (not shown) is conformally deposited directly on exposed surfaces of the structure 100 within the gate cavities or openings and spaces left by removing the sacrificial gates 118 and the sacrificial nanosheets 106 according to known techniques. For example, the gate dielectric is conformally deposited on exposed surfaces of the channel nanosheets 108 and the inner spacers 134.

The gate dielectric is composed of any known gate dielectric materials, for example, oxide, nitride, and/or oxynitride. In an example, the gate dielectric can be a high-k material having a dielectric constant greater than silicon dioxide. Exemplary high-k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3 and each value of y is independently from 0 to 2. In some embodiments, a multilayered gate dielectric structure including different gate dielectric materials. For example, a silicon dioxide layer and a high-k gate dielectric layer can be formed and used together as the gate dielectric. In at least one embodiment, the gate dielectric is composed of hafnium oxide.

Next, the work function metal (not shown) is conformally deposited on the gate dielectric formed within the gate cavities according to known techniques. In at least one embodiment, the work function metal is made of the same conductive material across the entire structure. In at least another embodiment, the work function metal is made from different conductive materials in each of the devices illustrated the figures. In doing so, the different conductive materials would be deposited successively according to the design parameters and desired operation characteristics.

The work function metal can include any known conductive gate material including, for example, doped polysilicon, an elemental metal (e.g., tungsten, titanium, tantalum, aluminum, nickel, ruthenium, palladium and platinum), an alloy of at least two elemental metals, an elemental metal nitride (e.g., tungsten nitride, aluminum nitride, and titanium nitride), an elemental metal silicide (e.g., tungsten silicide, nickel silicide, and titanium silicide), or titanium cabon (TiC), titanium alumunm (TiAl), titanium aluminum cabron (TiAlC), or multilayered combinations thereof. In some embodiments, the work function metal can include an nFET gate metal. In other embodiments, the work function metal can include a pFET gate metal. When multiple gate cavities are formed, as illustrated herein, embodiments of the present invention explicitly contemplate forming an nFET in at least one of the gate cavities and a pFET in at least another one of the gate cavities.

In some embodiments, a gate metal or a contact metal, is deposited directly on the work function metal, and fills the gate cavities. The gate metal may include any suitable conductive material, such as, for example, copper, ruthenium, aluminum, tungsten, cobalt, or alloys thereof. After deposition, excess gate metal can be polished using known techniques.

Next, the gate structures 142 are recessed according to known techniques. Specifically, for example, one or more suitable etching techniques such as dry etch, wet etch, or combination of both may be used to recess the gate structures 142. In all cases, the chosen etching technique shall be selective to underlying structures, such as for example, the sidewall spacers 122 and the dielectric layer 140, as illustrated.

Next, the gate caps 144 of the present embodiment are formed directly on the recessed surfaces of the gate structures 142, and more specifically fill the voids created by recessing the gate structures 142 as illustrated and according to known techniques. Specifically, a blanket dielectric layer is deposited across the structure 100 followed by a chemical mechanical polishing technique to remove excess unwanted dielectric material from upper surfaces of the structure 100. As a result, topmost surfaces of the gate caps 144 will be flush, or substantially flush, with topmost surfaces of the sidewall spacers 122 and the dielectric layer 140.

The sidewall spacers 122 and the gate caps 144 separate and electrically insulate the gate structures 142 from subsequently formed structures, such as, for example, contact structures. The sidewall spacers 122 are critical for electrically insulating the gate structures 142 from any subsequently formed source drain regions or contact structures. The gate caps 144 may further protect the gate structures 142 during subsequent processing. In at least one embodiment, the sidewall spacers 122 and the gate caps 144 include silicon nitride, silicon boron nitride, silicon carbon nitride, silicon boron carbon nitride, or other known equivalents.

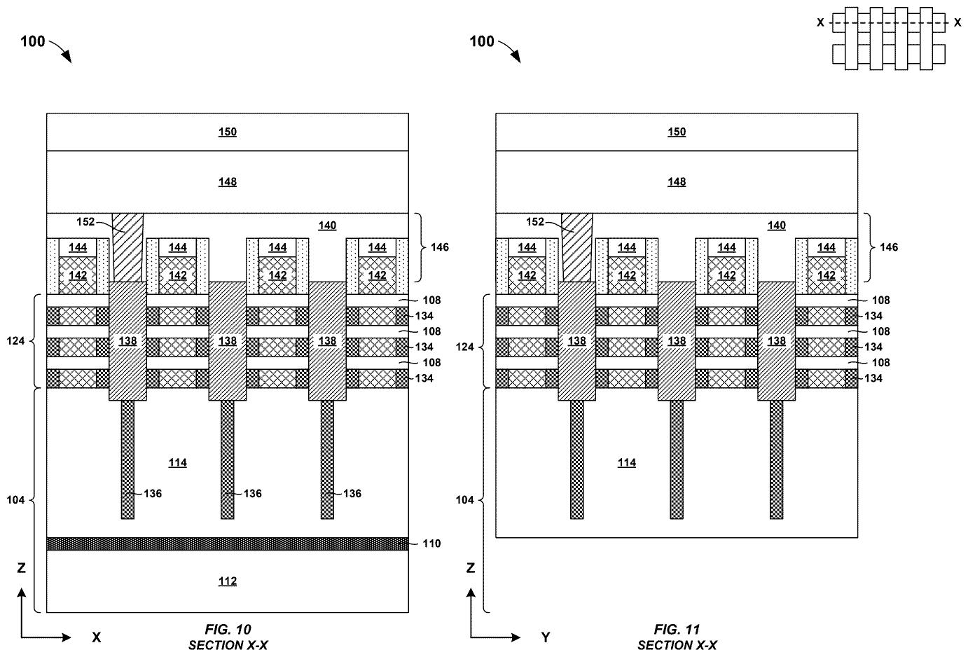

Referring now to FIG. 10, the structure 100 is shown after forming a middle-of-line 146, a back-end-of-line 148, a carrier wafer 150 according to an embodiment of the invention. FIG. 10 depicts a cross-sectional view taken along line X-X.

The middle-of-line 146 includes source drain contacts 152 and gate contacts (not shown) which may be generally referred to as middle-of-line contacts. The source drain contacts 152 and the gate contacts are formed according to known techniques. First, additional interlayer dielectric material is deposited according to known techniques. The dielectric layer 140 illustrated in the figures includes the additional interlayer dielectric material. Next, portions of the dielectric layer 140 are removed to expose the source drain regions 138. The openings are then filled with a conductive material to form the middle-of-line contacts according to known techniques. The middle-of-line contacts include any suitable conductive material, such as, for example, copper, ruthenium, aluminum, tungsten, cobalt, or alloys thereof. In some embodiments, a metal silicide is formed at the bottom of the contact trenches prior to filling them with the conductive material.

The back-end-of-line 148 may include vias and metal lines which may be generally referred to as back-end-of-line interconnects. The vias and the metal lines are formed according to known techniques.

Finally, the carrier wafer 150 is secured to a top of the structure 100 according to an embodiment of the invention. The carrier wafer 150 is attached, or removably secured, to the back-end-of-line 148. In general, and not depicted, the carrier wafer 150 may be thicker than the other layers. Temporarily bonding the structure 100 to a thicker carrier provides improved handling and additional support for backside processing of thin wafers. After backside processing described below, the structure 100 may be de-bonded, or removed, from the carrier wafer 150 according to known techniques.

Referring now to FIG. 11, the structure 100 is shown after flipping the assembly and recessing the substrate 104 according to an embodiment of the invention. FIG. 11 depicts a cross-sectional view taken along line X-X.

The structure 100 is flipped 180 degrees to prepare for backside processing. In general, backside processing includes fabrication or processing of the structure 100 opposite the active device and wiring layers. Next, the substrate 104 is recessed according to known techniques. Specifically, the base substrate 112 and the etch stop layer 110 are recessed or completely removed to expose the top semiconductor layer 114, as shown. It is noted, the orientation of the cross-sectional views referenced and illustrated hereafter will remain unchanged despite the actualities of flipping of the structure 100 for purposes of fabrication. As such, all references to “upper”, “lower”, “right”, “left”, “vertical”, “horizontal”, “top”, “bottom”, and derivatives thereof shall continue to relate to the disclosed structures and methods, as oriented in the drawing figures.

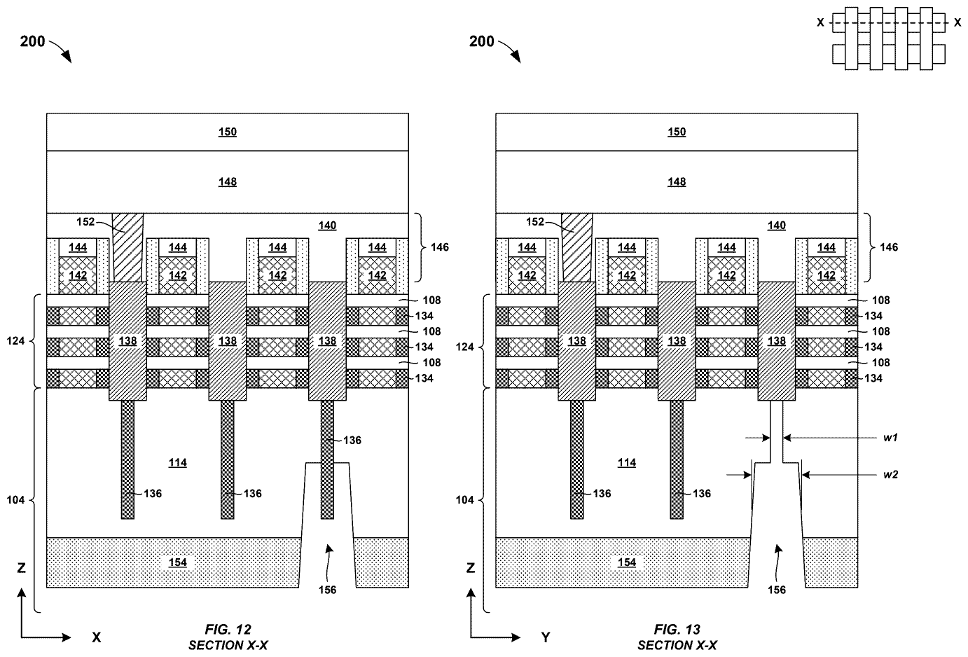

Referring now to FIG. 12-15, a structure 200 is shown during intermediate steps of a method of fabricating a nanosheet transistor structure according to an embodiment of the invention. The intermediate steps illustrated in FIG. 2-11 precede the intermediate steps illustrated in FIG. 12-15. As previously indicated, FIG. 2-15 illustrate an embodiment and FIG. 2-11 and 16-21 illustrate a different embodiment, with FIG. 2-11 being common to both embodiments.

Referring now to FIG. 12, the structure 200 is shown after forming a backside dielectric layer 154 and backside contact trenches 156 according to an embodiment of the invention. FIG. 12 depicts a cross-sectional view taken along line X-X.

First, the backside dielectric layer 154 is deposited according to known techniques. Specifically, a backside dielectric material is blanket deposited across the backside of the structure 200. The backside dielectric layer 154 completely covers the top semiconductor layer 114, as illustrated. After deposition, known chemical mechanical polishing may be used to remove excess portions of the backside dielectric material from bottom surfaces of the structure 200. According to the disclosed embodiments, chemical mechanical polishing is used to planarize the surface of the backside dielectric layer 154.

Next, a mask (not shown) is deposited and subsequently patterned to expose certain portions of the structure 200 according to known techniques. The mask can be an organic planarization layer (OPL) or a layer of material that is capable of being planarized or etched by known techniques. In an embodiment, for example, the mask can be an amorphous carbon layer able to withstand subsequent processing temperatures. The mask can preferably have a thickness sufficient to cover existing structures. After depositing the mask, a dry etching technique is applied to pattern or recess the mask according to known techniques. The mask is patterned consistent with a size and a location of subsequently formed backside contact structures. For example, after patterning the mask, portions of the structure 200 in contact regions are exposed.

Next, exposed portions of the backside dielectric layer 154 and underlying portions of the top semiconductor layer 114 are then selectively removed to form the backside contact trenches 156 according to known techniques. Specifically, the portions of the backside dielectric layer 154 and underlying portions of the top semiconductor layer 114 are removed using known etching techniques suitable to remove silicon selective to surrounding dielectrics, as illustrated.

In an embodiment, the portions of the backside dielectric layer 154 and underlying portions of the top semiconductor layer 114 are removed using an anisotropic etch such as, for example, reactive ion etching (RIE). After removing the portions of the backside dielectric layer 154 and underlying portions of the top semiconductor layer 114, portions of the bottom inner spacers 136 become exposed within the backside contact trenches 156, as illustrated. Significant to the embodiments disclosed herein, etching must continue until at least bottom portions of the bottom inner spacers 136 are exposed in the contact regions. Meanwhile, the bottom inner spacers 136 in non-contact regions remain substantially surrounded by the top semiconductor layer 114.

Specific to the disclosed embodiments, it is noted that the backside contact trenches 156 only partially extend into the top semiconductor layer 114. Said differently, etching of the backside contact trenches 156 continues until approximately 50 percent of the bottom inner spacers 136 is exposed, as illustrated. Furthermore, in all cases, each of the backside contact trenches 156 is wider than each of the bottom inner spacers 136.

Referring now to FIG. 13, the structure 200 is shown after removing some of the bottom inner spacers 136 according to an embodiment of the invention. FIG. 13 depicts a cross-sectional view taken along line X-X.

The bottom inner spacers 136 exposed within the backside contact trenches 156 are entirely removed according to known techniques. Specifically, the bottom inner spacers 136 exposed within the backside contact trenches 156 are removed using known etching techniques suitable to remove nitride containing dielectric materials selective to the surrounding elements, for example the top semiconductor layer 114 and the source drain regions 138. In doing so, bottommost surfaces of the source drain regions 138 become exposed, as illustrated. Known directional etching techniques, for example reactive ion etching, may be used to remove the bottom inner spacers 136 exposed within the backside contact trenches 156. After etching, the backside contact trenches 156 will have top portions with a first width (w1) and bottom portions with a second width (w2), where the first width (w1) is less than the second width (w2). Furthermore, the first width (w1) of each of the backside contact trenches 156 is less than a width of each of the source drain regions 138, as illustrated.

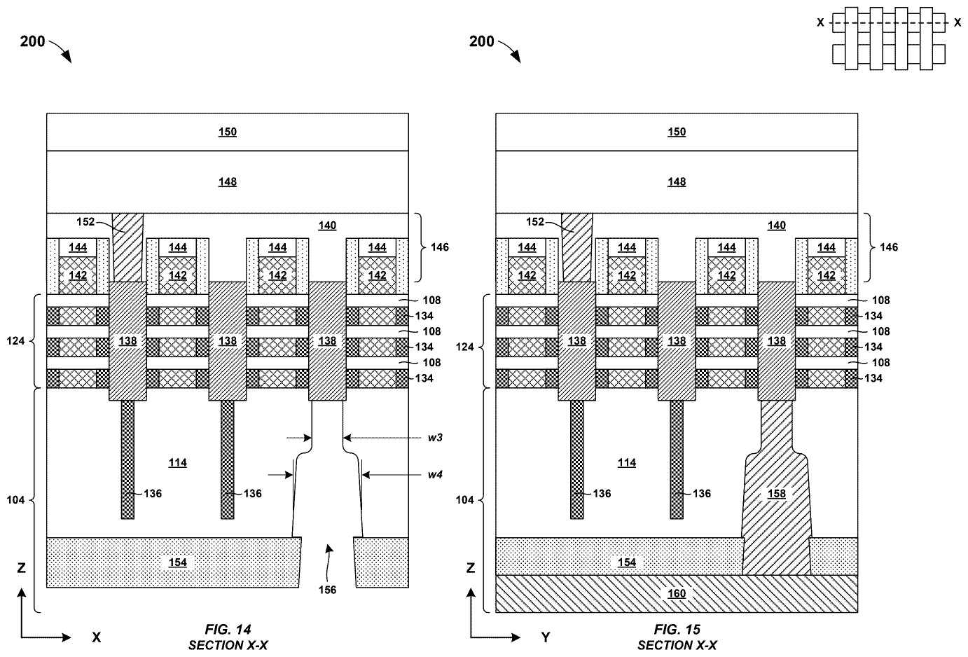

Referring now to FIG. 14, the structure 200 is shown after removing portions of the top semiconductor layer 114 from within the backside contact trenches 156 according to an embodiment of the invention. FIG. 14 depicts a cross-sectional view taken along line X-X.

Portions of the top semiconductor layer 114 are removed from within the backside contact trenches 156 according to known techniques. Specifically, an isotropic etching technique is applied to the backside of the structure 200 to remove sidewall portions of the top semiconductor layer 114 and effectively enlarge the dimensions of the backside contact trenches 156. In general, etching is designed to be selective to the source drain regions 138 and the backside dielectric layer 154, as illustrated.

After etching, the top portions of the backside contact trenches 156 will have a third width (w3) and the bottom portions of the backside contact trenches 156 will have a fourth width (w4), where the third width (w3) is less than the fourth width (w4). In at least one embodiment, the third width (w3) is less than the width of each of the source drain regions 138 and the fourth width (w4) is greater than the width of each of the source drain regions 138, as illustrated. In another embodiment, both the third width (w3) and the fourth width (w4) are each less than the width of each of the source drain regions 138. In yet another embodiment, both the third width (w3) and the fourth width (w4) are each greater than the width of each of the source drain regions 138.

Referring now to FIG. 15, the structure 200 is shown after forming backside contact structures 158 and backside wiring layers 160 according to an embodiment of the invention. FIG. 15 depicts a cross-sectional view taken along line X-X.

First, the backside of the structure 200 is pre-cleaned according to known techniques. It is noted that pre-cleaning may, according to an embodiment, etch the backside dielectric layer 154. In doing so, a thickness of the backside dielectric layer 154 is reduced and the backside contact trenches 156 at the backside dielectric layer 154 are enlarged, as illustrated.

Nest, the backside contact trenches 156 are filled with a conductive material to form the backside contact structures 158 according to known techniques. The backside contact structures 158 may include any suitable conductive material, such as, for example, copper, ruthenium, aluminum, tungsten, cobalt, or alloys thereof. In some embodiments, first metal silicide regions (not shown) are formed at the top of the backside contact trenches 156 prior to filling them with the conductive material, and according to known techniques. In doing so, second metal silicide regions (not shown) may also form along sidewalls of the top semiconductor layer 114 exposed within the backside contact trenches 156. Silicide formation is otherwise believed to be conventional and not a subject of the disclose embodiments.

Enlarging the backside contact trenches 156, as previously described above, ensures the backside contact structures 158 are void free and low resistance. For example, the first width (w1) (FIG. 13) of the top portion of the backside contact trenches 156 will otherwise be too small and can prohibit adequate deposit backside contact materials.

After deposition, excess conductive material can be polished using known techniques until bottommost surfaces of the backside contact structures 158 are flush, or substantially flush, with bottommost surfaces of the backside dielectric layer 154, as illustrated. After polishing, bottommost surfaces of the backside contact structures 158 are substantially flat. It is noted, the backside contact structures 158 may include, for example, backside source drain contacts, as illustrated, as well as backside gate contacts (not shown).

After forming the backside contact structures 158, the backside wiring layers 160 are subsequently formed according to known techniques. The backside wiring layers 160 typically include at least backside power rails and a backside power delivery network.

According to the embodiment illustrated in FIG. 15, the transistor structures represented by the structure 200 have some distinctive notable features. For instance, the structure 200 includes at least one of the backside contact structures 158 directly beneath a first source drain region, for example one of the source drain regions 138, and one of the bottom inner spacers 136 directly beneath a second source drain region, for example another one of the source drain regions 138, adjacent to the at least one of the backside contact structures 158.

Unlike the structure 300 described below, the backside contact structures 158 of the structure 200 are substantially surrounded by a substrate material, specifically the top semiconductor layer 114.

Additionally, the top semiconductor layer 114 of the structure 200 surrounds bottoms of the bottom inner spacers 136 thereby physically separating the bottom inner spacers 136 from the backside wiring layers 160. As such, bottommost surfaces of the bottom inner spacers 136 are higher than bottommost surfaces of the backside contact structures 158.

Finally, the structure 200, and associated method to fabricate, do not require selective removal of a silicon germanium placeholder.

With continued reference to FIG. 15, and according to an embodiment, the structure 200 includes a backside contact structure beneath a first source drain region, and a bottom inner spacer directly beneath a second source drain region adjacent to the backside contact structure.

With continued reference to FIG. 15, and according to an embodiment, bottommost surfaces of the first source drain region and second source drain region are below bottommost surfaces of corresponding gate structures.

With continued reference to FIG. 15, and according to an embodiment, a width of the bottom inner spacer is less than a width of the second source drain region.

With continued reference to FIG. 15, and according to an embodiment, a first width of a top portion of the backside contact structure is less than a second width of a bottom portion of the backside contact structure.

With continued reference to FIG. 15, and according to an embodiment, the first width of the backside contact structure is less than a width of the first source drain region, and where the second width of the backside contact structure is greater than a width of the first source drain region.

With continued reference to FIG. 15, and according to an embodiment, a top surface of the backside contact structure is substantially flush with a top surface of the bottom inner spacer.

With continued reference to FIG. 15, and according to an embodiment, the bottom inner spacer is a same material as a plurality of inner spacers arranged between and physically separating the second source drain region from neighboring gate structures.

With continued reference to FIG. 15, and according to an embodiment, the structure 200 includes a backside contact structure beneath a first source drain region, and a bottom inner spacer directly beneath a second source drain region adjacent to the backside contact structure, where the backside contact structure is taller than the bottom inner spacer.

With continued reference to FIG. 15, and according to an embodiment, the structure 200 includes a backside contact structure beneath a first source drain region, and a bottom inner spacer directly beneath a second source drain region adjacent to the backside contact structure, where a height of the backside contact structure is substantially equal to a height of the bottom inner spacer.

Various examples may possibly be described by one or more of the following features in the following numbered clauses:

Clause 1: A nanosheet semiconductor structure including a backside contact structure beneath a first source drain region, and a bottom inner spacer directly beneath a second source drain region adjacent to the backside contact structure.

Clause 2: The semiconductor structure according to clause 1, where bottommost surfaces of the first source drain region and second source drain region are below bottommost surfaces of corresponding gate structures.

Clause 3: The semiconductor structure according to clauses 1 and 2, where a width of the bottom inner spacer is less than a width of the second source drain region.

Clause 4: The semiconductor structure according to clauses 1, 2, and 3, where a first width of a top portion of the backside contact structure is less than a second width of a bottom portion of the backside contact structure.

Clause 5: The semiconductor structure according to clauses 1, 2, 3, and 4, where the first width of the backside contact structure is less than a width of the first source drain region, and where the second width of the backside contact structure is greater than a width of the first source drain region.

Clause 6: The semiconductor structure according to clauses 1, 2, 3, 4, and 5, where a top surface of the backside contact structure is substantially flush with a top surface of the bottom inner spacer.

Clause 7: The semiconductor structure according to clauses 1, 2, 3, 4, 5, and 6, where the bottom inner spacer is a same material as a plurality of inner spacers arranged between and physically separating the second source drain region from neighboring gate structures.

Clause 8: A nanosheet semiconductor structure including: a backside contact structure beneath a first source drain region, and a bottom inner spacer directly beneath a second source drain region adjacent to the backside contact structure, where the backside contact structure is taller than the bottom inner spacer.

Clause 9: The semiconductor structure according to clause 8, where bottommost surfaces of the first source drain region and second source drain region are below bottommost surfaces of corresponding gate structures.

Clause 10: The semiconductor structure according to clauses 8 and 9, where a width of the bottom inner spacer is less than a width of the second source drain region.

Clause 11: The semiconductor structure according to clauses 8, 9, and 10, where a first width of a top portion of the backside contact structure is less than a second width of a bottom portion of the backside contact structure.

Clause 12: The semiconductor structure according to clauses 8, 9, 10, and 11, where the first width of the backside contact structure is less than a width of the first source drain region, and where the second width of the backside contact structure is greater than a width of the first source drain region.

Clause 13: The semiconductor structure according to clauses 8, 9, 10, 11, and 12, where a top surface of the backside contact structure is substantially flush with a top surface of the bottom inner spacer.

Clause 14: The semiconductor structure according to clauses 8, 9, 10, 11, 12, and 13, where the bottom inner spacer is a same material as a plurality of inner spacers arranged between and physically separating the second source drain region from neighboring gate structures.

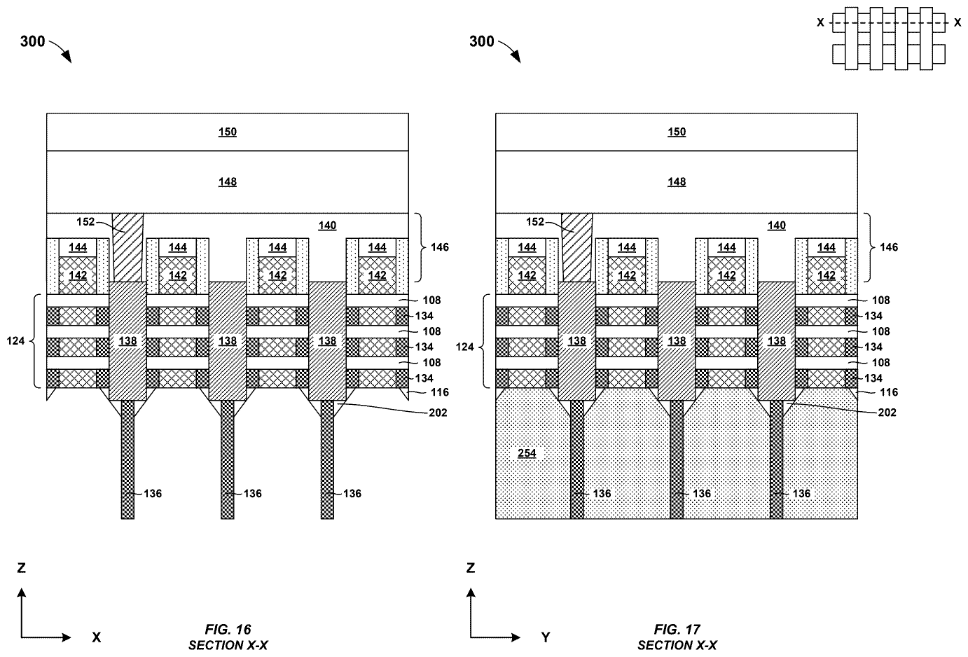

Referring now to FIG. 16-21, a structure 300 is shown during intermediate steps of a method of fabricating a nanosheet transistor structure according to another embodiment of the invention. The intermediate steps illustrated in FIG. 2-11 precede the intermediate steps illustrated in FIG. 16-21. As previously indicated, FIG. 2-15 illustrate an embodiment and FIG. 2-11 and 16-21 illustrate a different embodiment, with FIG. 2-11 being common to both embodiments.

Referring now to FIG. 16, the structure 300 is shown after recessing the top semiconductor layer 114 according to an embodiment of the invention. FIG. 16 depicts a cross-sectional view of the structure 300 taken along line X-X.

The top semiconductor layer 114 is recessed according to known techniques. Specifically, a majority of the top semiconductor layer 114 is recessed using an isotropic etch process, which etches silicon selective to the nitride containing dielectric materials of the bottom inner spacers 136. For example, in at least one embodiment, an ammonia silicon etch is used to recess the top semiconductor layer 114. According to the illustrated embodiment, etching continues until a majority of the top semiconductor layer 114 is removed without exposing or damaging the source drain regions 138. In a preferred embodiment, etching shall not damage the source drain regions 138. In such cases, remaining portions 202 of the top semiconductor layer 114 will remain in the corners where the bottom inner spacers 136 intersect with the source drain regions 138 and the corners where the source drain regions 138 intersect with the inner spacers 134, as illustrated.

Referring now to FIG. 17, the structure 300 is shown after forming a backside dielectric layer 254 according to an embodiment of the invention. FIG. 17 depicts a cross-sectional view of the structure 300 taken along line X-X.

First, the backside dielectric layer 254 is deposited according to known techniques. Specifically, a backside dielectric material is blanket deposited across the backside of the structure 300. The backside dielectric layer 254 completely covers the remaining portions 202 of the top semiconductor layer 114 as well as the bottom inner spacers 136, as illustrated.

After deposition, known chemical mechanical polishing may be used to remove excess portions of the backside dielectric material from bottom surfaces of the structure 300. As a result, bottommost surfaces of the backside dielectric layer 254 will be flush, or substantially flush, with bottommost surfaces of the bottom inner spacers 136, as illustrated.

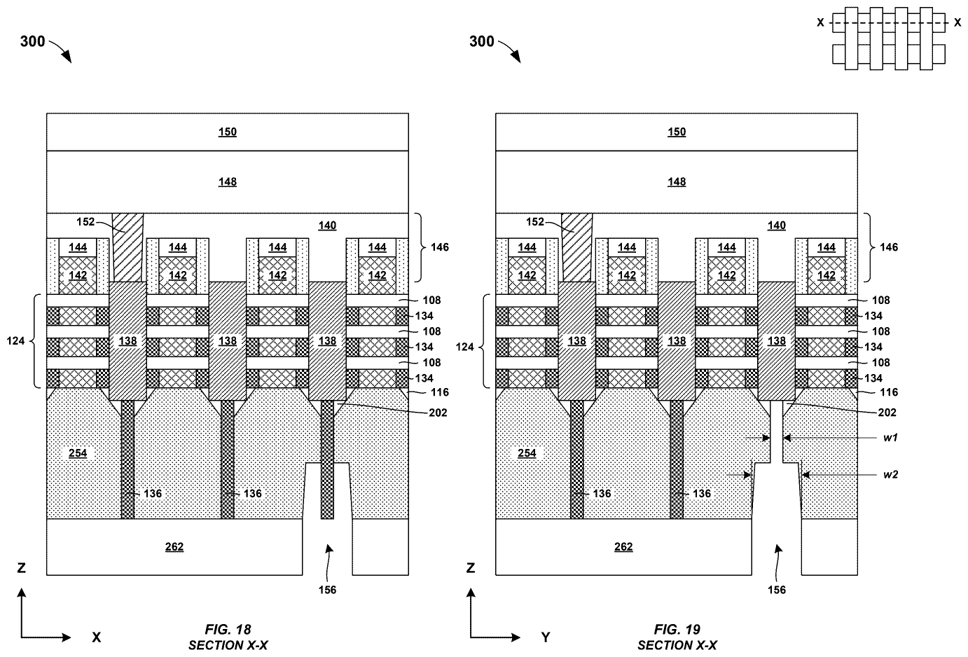

Referring now to FIG. 18, the structure 300 is shown after forming a backside mask 262 and backside contact trenches 156 according to an embodiment of the invention. FIG. 18 depicts a cross-sectional view of the structure 300 taken along line X-X.

First, a backside mask 262 is deposited and subsequently patterned to expose certain portions of the structure 300 according to known techniques. The backside mask 262 can be an organic planarization layer (OPL) or a layer of material that is capable of being planarized or etched by known techniques. In an embodiment, for example, the backside mask 262 can be an amorphous carbon layer able to withstand subsequent processing temperatures. The backside mask 262 can preferably have a thickness sufficient to cover existing structures. After depositing the backside mask 262, a dry etching technique is applied to pattern or recess the backside mask 262 according to known techniques. The backside mask 262 is patterned consistent with a size and a location of subsequently formed backside contact structures. For example, after patterning the backside mask 262, portions of the structure 300 in contact regions are exposed.

Next, exposed portions of the backside dielectric layer 254 are then selectively removed to form the backside contact trenches 156 according to known techniques. Specifically, the portions of the backside dielectric layer 254 are removed using known etching techniques suitable to remove backside dielectrics selective to surrounding elements, such as the bottom inner spacers 136, as illustrated.

In an embodiment, the portions of the backside dielectric layer 254 are removed using an anisotropic etch such as, for example, reactive ion etching (RIE). After removing the portions of the backside dielectric layer 254, portions of the bottom inner spacers 136 become exposed within the backside contact trenches 156, as illustrated. Significant to the embodiments disclosed herein, etching must continue until at least bottom portions of the bottom inner spacers 136 are exposed in the contact regions. Meanwhile, the bottom inner spacers 136 in non-contact regions remain substantially surrounded by the backside dielectric layer 254.

Specific to the disclosed embodiments, it is noted that the backside contact trenches 156 only partially extend into the backside dielectric layer 254. Said differently, etching of the backside contact trenches 156 continues until approximately 50 percent of the bottom inner spacers 136 is exposed, as illustrated. Furthermore, in all cases, each of the backside contact trenches 156 is wider than each of the bottom inner spacers 136.

Referring now to FIG. 19, the structure 300 is shown after removing some of the bottom inner spacers 136 according to an embodiment of the invention. FIG. 19 depicts a cross-sectional view of the structure 300 taken along line X-X.

The bottom inner spacers 136 exposed within the backside contact trenches 156 are entirely removed according to known techniques. Specifically, the bottom inner spacers 136 exposed within the backside contact trenches 156 are removed using known etching techniques suitable to remove nitride containing dielectric materials selective to the surrounding elements, for example the backside dielectric layer 254, the remaining portions 202 of the top semiconductor layer 114, and the source drain regions 138. In doing so, bottommost surfaces of the source drain regions 138 become exposed, as illustrated. Known directional etching techniques, for example reactive ion etching, may be used to remove the bottom inner spacers 136 exposed within the backside contact trenches 156. After etching, the backside contact trenches 156 will have top portions with a first width (w1) and bottom portions with a second width (w2), where the first width (w1) is less than the second width (w2). Furthermore, the first width (w1) of each of the backside contact trenches 156 is less than a width of each of the source drain regions 138, as illustrated.

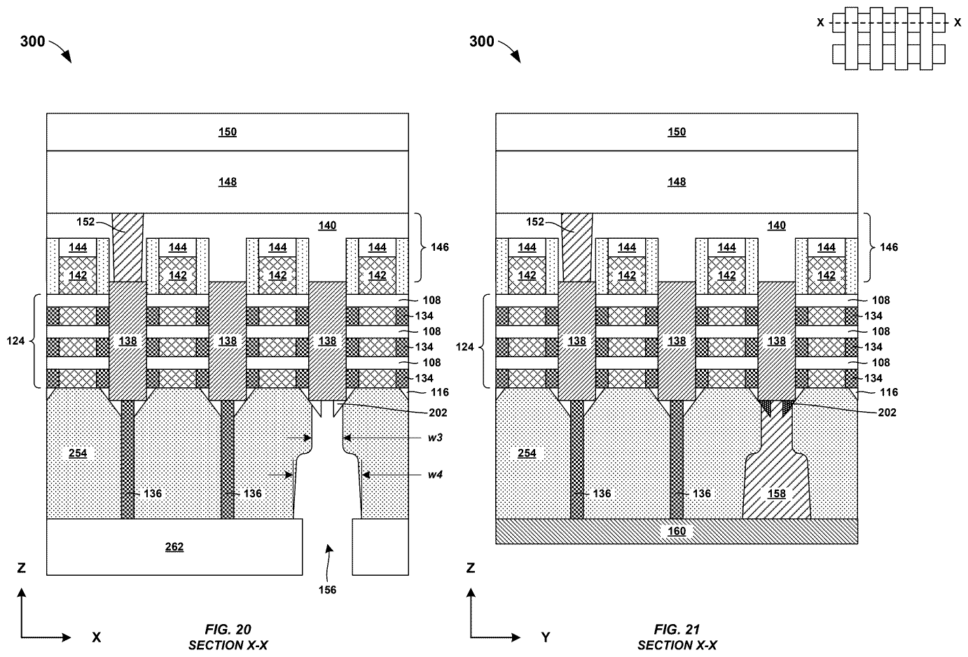

Referring now to FIG. 20, the structure 300 is shown after removing portions of the backside dielectric layer 254 from within the backside contact trenches 156 according to an embodiment of the invention. FIG. 20 depicts a cross-sectional view of the structure 300 taken along line X-X.

Portions of the backside dielectric layer 254 are removed from within the backside contact trenches 156 according to known techniques. Specifically, an isotropic etching technique is applied to the backside of the structure 300 to remove sidewall portions of the backside dielectric layer 254 and effectively enlarge the dimensions of the backside contact trenches 156. In general, etching is designed to be selective to the source drain regions 138, the remaining portions 202 of the top semiconductor layer 114, and the backside mask 262, as illustrated.

After etching, the top portions of the backside contact trenches 156 will have a third width (w3) and the bottom portions of the backside contact trenches 156 will have a fourth width (w4), where the third width (w3) is less than the fourth width (w4). In at least one embodiment, the third width (w3) is less than the width of each of the source drain regions 138 and the fourth width (w4) is greater than the width of each of the source drain regions 138, as illustrated. In another embodiment, both the third width (w3) and the fourth width (w4) are each less than the width of each of the source drain regions 138. In yet another embodiment, both the third width (w3) and the fourth width (w4) are each greater than the width of each of the source drain regions 138.

Referring now to FIG. 21, the structure 300 is shown after removing portions of the top semiconductor layer 114 from within the backside contact trenches 156 according to an embodiment of the invention. FIG. 21 depicts a cross-sectional view of the structure 300 taken along line X-X.

First, the backside mask 262 is removed according to known techniques. In an embodiment, the backside mask 262 is removed using known techniques, such as, for example, ashing.

Next. the backside contact trenches 156 are filled with a conductive material to form the backside contact structures 158 according to known techniques. The backside contact structures 158 may include any suitable conductive material, such as, for example, copper, ruthenium, aluminum, tungsten, cobalt, or alloys thereof. In some embodiments, first metal silicide regions (not shown) are formed at the top of the backside contact trenches 156 prior to filling them with the conductive material, and according to known techniques. In doing so, second metal silicide regions (not shown) may also form along sidewalls of the top semiconductor layer 114 exposed within the backside contact trenches 156. Although silicide formation is otherwise believed to be conventional and not a subject of the disclose embodiments, according to an embodiment the remaining portions 202 of the top semiconductor layer 114, exposed within the backside contact trenches 156 may be converted, in part or in whole, to a silicide. Alternatively, according to another embodiment, the remaining portions 202 of the top semiconductor layer 114, exposed within the backside contact trenches 156 are doped using known diffusion or implant techniques before silicide formation.

Enlarging the backside contact trenches 156, as previously described above, ensures the backside contact structures 158 are void free and low resistance. For example, the first width (w1) (FIG. 19) of the top portion of the backside contact trenches 156 will otherwise be too small and can prohibit adequate deposit backside contact materials.

After deposition, excess conductive material can be polished using known techniques until bottommost surfaces of the backside contact structures 158 are flush, or substantially flush, with bottommost surfaces of the backside dielectric layer 254, as illustrated. After polishing, bottommost surfaces of the backside contact structures 158 are substantially flat. It is noted, the backside contact structures 158 may include, for example, backside source drain contacts, as illustrated, as well as backside gate contacts (not shown).

After forming the backside contact structures 158, the backside wiring layers 160 are subsequently formed according to known techniques. The backside wiring layers 160 typically include at least backside power rails and a backside power delivery network.

According to the embodiment illustrated in FIG. 21, the transistor structures represented by the structure 300 have some distinctive notable features. For instance, the structure 300 includes at least one of the backside contact structures 158 directly beneath a first source drain region, for example one of the source drain regions 138, and a bottom inner spacer 136 directly beneath a second source drain region, for example another one of the source drain regions 138, adjacent to the at least one of the backside contact structures 158.

Unlike the structure 200 described above, the backside contact structures 158 of the structure 300 are substantially surrounded by a dielectric material, specifically the backside dielectric layer 254.

Additionally, bottommost surfaces of the bottom inner spacers 136 directly contact the backside wiring layers 160. As such, bottommost surfaces of the bottom inner spacers 136 are substantially flush with bottommost surfaces of the backside contact structures 158.

Finally, the structure 300, and associated method to fabricate, do not require selective removal of a silicon germanium placeholder.

With continued reference to FIG. 21, and according to an embodiment, the structure 300 includes a backside contact structure beneath a first source drain region, and a bottom inner spacer directly beneath a second source drain region adjacent to the backside contact structure.

With continued reference to FIG. 21, and according to an embodiment, bottommost surfaces of the first source drain region and second source drain region are below bottommost surfaces of corresponding gate structures.

With continued reference to FIG. 21, and according to an embodiment, a width of the bottom inner spacer is less than a width of the second source drain region.

With continued reference to FIG. 21, and according to an embodiment, a first width of a top portion of the backside contact structure is less than a second width of a bottom portion of the backside contact structure.

With continued reference to FIG. 21, and according to an embodiment, the first width of the backside contact structure is less than a width of the first source drain region, and where the second width of the backside contact structure is greater than a width of the first source drain region.

With continued reference to FIG. 21, and according to an embodiment, a top surface of the backside contact structure is substantially flush with a top surface of the bottom inner spacer.

With continued reference to FIG. 21, and according to an embodiment, the bottom inner spacer is a same material as a plurality of inner spacers arranged between and physically separating the second source drain region from neighboring gate structures.

With continued reference to FIG. 21, and according to an embodiment, the structure 300 includes a backside contact structure beneath a first source drain region, and a bottom inner spacer directly beneath a second source drain region adjacent to the backside contact structure, where the backside contact structure is taller than the bottom inner spacer.

With continued reference to FIG. 21, and according to an embodiment, the structure 300 includes a backside contact structure beneath a first source drain region, and a bottom inner spacer directly beneath a second source drain region adjacent to the backside contact structure, where a height of the backside contact structure is substantially equal to a height of the bottom inner spacer.

Various examples may possibly be described by one or more of the following features in the following numbered clauses:

Clause 1: A nanosheet semiconductor structure including a backside contact structure beneath a first source drain region, and a bottom inner spacer directly beneath a second source drain region adjacent to the backside contact structure.

Clause 2: The semiconductor structure according to clause 1, where bottommost surfaces of the first source drain region and second source drain region are below bottommost surfaces of corresponding gate structures.

Clause 3: The semiconductor structure according to clauses 1 and 2, where a width of the bottom inner spacer is less than a width of the second source drain region.

Clause 4: The semiconductor structure according to clauses 1, 2, and 3, where a first width of a top portion of the backside contact structure is less than a second width of a bottom portion of the backside contact structure.

Clause 5: The semiconductor structure according to clauses 1, 2, 3, and 4, where the first width of the backside contact structure is less than a width of the first source drain region, and where the second width of the backside contact structure is greater than a width of the first source drain region.

Clause 6: The semiconductor structure according to clauses 1, 2, 3, 4, and 5, where a top surface of the backside contact structure is substantially flush with a top surface of the bottom inner spacer.

Clause 7: The semiconductor structure according to clauses 1, 2, 3, 4, 5, and 6, where the bottom inner spacer is a same material as a plurality of inner spacers arranged between and physically separating the second source drain region from neighboring gate structures.

Clause 15: A nanosheet semiconductor structure including: a backside contact structure beneath a first source drain region, and a bottom inner spacer directly beneath a second source drain region adjacent to the backside contact structure, where a height of the backside contact structure is substantially equal to a height of the bottom inner spacer.

Clause 16: The semiconductor structure according to clause 15, where bottommost surfaces of the first source drain region and second source drain region are below bottommost surfaces of corresponding gate structures.

Clause 17: The semiconductor structure according to clauses 15 and 16, where a width of the bottom inner spacer is less than a width of the second source drain region.

Clause 18: The semiconductor structure according to clauses 15, 16, and 17, where a first width of a top portion of the backside contact structure is less than a second width of a bottom portion of the backside contact structure.

Clause 19: The semiconductor structure according to clauses 15, 16, 17, and 18, where the first width of the backside contact structure is less than a width of the first source drain region, and where the second width of the backside contact structure is greater than a width of the first source drain region.

Clause 20: The semiconductor structure according to clauses 15, 16, 17, 18, and 19, where a top surface of the backside contact structure is substantially flush with a top surface of the bottom inner spacer.

Clause 21: The semiconductor structure according to clauses 15, 16, 17, 18, 19, and 20 where the bottom inner spacer is a same material as a plurality of inner spacers arranged between and physically separating the second source drain region from neighboring gate structures.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A nanosheet semiconductor structure comprising:
a backside contact structure beneath a first source drain region; and
a bottom inner spacer directly beneath a second source drain region adjacent to the backside contact structure.

2. The nanosheet semiconductor structure according to claim 1, wherein bottommost surfaces of the first source drain region and second source drain region are below bottommost surfaces of corresponding gate structures.

3. The nanosheet semiconductor structure according to claim 1, wherein a width of the bottom inner spacer is less than a width of the second source drain region.

4. The nanosheet semiconductor structure according to claim 1, wherein a first width of a top portion of the backside contact structure is less than a second width of a bottom portion of the backside contact structure.

5. The nanosheet semiconductor structure according to claim 4, wherein the first width of the backside contact structure is less than a width of the first source drain region, and wherein the second width of the backside contact structure is greater than a width of the first source drain region.

6. The nanosheet semiconductor structure according to claim 1, wherein a top surface of the backside contact structure is substantially flush with a top surface of the bottom inner spacer.

7. The nanosheet semiconductor structure according to claim 1, wherein the bottom inner spacer is a same material as a plurality of inner spacers arranged between and physically separating the second source drain region from neighboring gate structures.

8. A nanosheet semiconductor structure comprising:
a backside contact structure beneath a first source drain region; and
a bottom inner spacer directly beneath a second source drain region adjacent to the backside contact structure, wherein the backside contact structure is taller than the bottom inner spacer.

9. The nanosheet semiconductor structure according to claim 8, wherein bottommost surfaces of the first source drain region and second source drain region are below bottommost surfaces of corresponding gate structures.

10. The nanosheet semiconductor structure according to claim 8, wherein a width of the bottom inner spacer is less than a width of the second source drain region.

11. The nanosheet semiconductor structure according to claim 8, wherein a first width of a top portion of the backside contact structure is less than a second width of a bottom portion of the backside contact structure.

12. The nanosheet semiconductor structure according to claim 11, wherein the first width of the backside contact structure is less than a width of the first source drain region, and wherein the second width of the backside contact structure is greater than a width of the first source drain region.

13. The nanosheet semiconductor structure according to claim 8, wherein a top surface of the backside contact structure is substantially flush with a top surface of the bottom inner spacer.

14. The nanosheet semiconductor structure according to claim 8, wherein the bottom inner spacer is a same material as a plurality of inner spacers arranged between and physically separating the second source drain region from neighboring gate structures.

15. A nanosheet semiconductor structure comprising:
a backside contact structure beneath a first source drain region; and
a bottom inner spacer directly beneath a second source drain region adjacent to the backside contact structure, wherein a height of the backside contact structure is substantially equal to a height of the bottom inner spacer.

16. The nanosheet semiconductor structure according to claim 15, wherein bottommost surfaces of the first source drain region and second source drain region are below bottommost surfaces of corresponding gate structures.

17. The nanosheet semiconductor structure according to claim 15, wherein a width of the bottom inner spacer is less than a width of the second source drain region.

18. The nanosheet semiconductor structure according to claim 15, wherein a first width of a top portion of the backside contact structure is less than a second width of a bottom portion of the backside contact structure.

19. The nanosheet semiconductor structure according to claim 18, wherein the first width of the backside contact structure is less than a width of the first source drain region, and wherein the second width of the backside contact structure is greater than a width of the first source drain region.

20. The nanosheet semiconductor structure according to claim 15, wherein a top surface of the backside contact structure is substantially flush with a top surface of the bottom inner spacer.
